(19) United States
(12) Patent Application Publication
(10) Pub. No.: US 2025/0003063 A1
(43) Pub. Date: Jan. 2, 2025

(54) Particle Coating Apparatus And Method Of Coating Particle

(71) Applicant: SEIKO EPSON CORPORATION, Tokyo (JP)

(72) Inventors: Teruaki NANBA, Chino (JP); Shinichi UEDA, Chino (JP); Ryujiro SAIBA, Matsumoto (JP); Kunio NISHIZAWA, Suwa (JP); Hiroyuki CHINO, Shiojiri (JP); Yoshihiro ITO, Chino (JP)

(21) Appl. No.: 18/757,714

(22) Filed: Jun. 28, 2024

(30) Foreign Application Priority Data
Jun. 29, 2023 (JP) 2023-106814

(51) Int. Cl. C23C 16/44; C23C 16/02; C23C 16/455; C23C 16/458; C23C 16/505

(52) U.S. Cl. CPC C23C 16/4417; C23C 16/0218; C23C 16/4412; C23C 16/45534; C23C 16/45536; C23C 16/4583; C23C 16/505

(57) ABSTRACT

A particle coating apparatus configured to form a coating film on a surface of a particle of a treatment target powder using an atomic layer deposition method includes a processing chamber, a powder supply unit which includes an anterior chamber configured to house the treatment target powder, and which is configured to supply the treatment target powder into the processing chamber in a state of being isolated from outside air, a supply switching unit which is disposed between the anterior chamber and the processing chamber, and which is configured to switch supply of the treatment target powder, a material gas supply unit configured to supply a material gas into the processing chamber, an oxidizing agent supply unit configured to supply an oxidizing agent into the processing chamber, a processing chamber exhaust unit configured to exhaust the processing chamber, and a powder layer holding unit which is disposed in the processing chamber, and which is configured to hold a powder layer formed of the treatment target powder supplied from the anterior chamber and laid in a layer.

The present application is based on, and claims priority from JP Application Serial Number 2023-106814, filed Jun. 29, 2023, the disclosure of which is hereby incorporated by reference herein in its entirety.

### BACKGROUND

### 1. Technical Field

The present disclosure relates to a particle coating apparatus and a method of coating particles.

### 2. Related Art

In the magnetic powder used for an inductor or the like, it is necessary to perform an insulating treatment on surfaces of particles to suppress an eddy current flowing between the particles or insulate the particles from each other. Therefore, a method of forming an insulating film on the surfaces of the particles of magnetic powder using various film formation methods has been studied.

For example, JP-A-2021-085050 discloses a particle coating apparatus that forms an insulating film on a surface of a soft magnetic metal particle by an atomic layer deposition (ALD) method, which is one type of a chemical vapor deposition method. According to the atomic layer deposition method, an insulating film thin and uniform in film thickness can be formed.
JP-A-2021-085050 is an example of the related art.
JP-A-2021-085050 does not describe a method of supplying soft magnetic metal particles into a chamber. Therefore, the particle coating apparatus disclosed in JP-A-2021-085050 cannot efficiently supply soft magnetic metal particles to be used for forming the coating film. As a result, there is a problem that the production efficiency of the coated particles cannot sufficiently be increased.

### SUMMARY

A particle coating apparatus according to an application example of the present disclosure is a particle coating apparatus configured to form a coating film on a surface of a particle of a treatment target powder using an atomic layer deposition method, including:
a processing chamber;
a powder supply unit which includes an anterior chamber configured to house the treatment target powder, and which is configured to supply the treatment target powder into the processing chamber in a state of being isolated from outside air;
a supply switching unit which is disposed between the anterior chamber and the processing chamber, and which is configured to switch supply of the treatment target powder;
a material gas supply unit configured to supply a material gas into the processing chamber;
an oxidizing agent supply unit configured to supply an oxidizing agent into the processing chamber;
a processing chamber exhaust unit configured to exhaust the processing chamber; and
a powder layer holding unit which is disposed in the processing chamber, and which is configured to hold a powder layer formed of the treatment target powder supplied from the anterior chamber and laid in a layer.

A method of coating a particle according to an application example of the present disclosure is a method of coating a particle for forming a coating film on a surface of a particle of a treatment target powder using an atomic layer deposition method, including:
supplying the treatment target powder housed in an anterior chamber airtightly coupled to a processing chamber into the processing chamber in a state of being isolated from outside air;
forming a powder layer by laying the treatment target powder supplied into the processing chamber in a layer; and
forming the coating film in the powder layer in the processing chamber using the atomic layer deposition method.

### BRIEF DESCRIPTION OF THE DRAWINGS

FIG. 1 is a cross-sectional view illustrating a particle coating apparatus according to an embodiment.

FIG. 2 is a cross-sectional view schematically showing an example of a coated particle manufactured by the particle coating apparatus shown in FIG. 1.

FIG. 3 is a process diagram showing a method of coating particles according to the embodiment.

FIG. 4 is a cross-sectional view showing an example of a method of forming a powder layer.

FIG. 5 is a cross-sectional view showing an example of the method of forming the powder layer.

FIG. 6 is a cross-sectional view showing an example of the method of forming the powder layer.

FIG. 7 is a cross-sectional view showing an example of the method of forming the powder layer.

FIG. 8 is a cross-sectional view showing an example of the method of forming the powder layer.

FIG. 9 is a perspective view illustrating a squeegee provided to a particle coating apparatus according to a first modified example.

FIG. 10 is a cross-sectional view illustrating a processing chamber provided to a particle coating apparatus according to a second modified example.

### DESCRIPTION OF EMBODIMENTS

Hereinafter, an exemplary embodiment of a particle coating apparatus and a method of coating particles according to the present disclosure will be described in detail based on the accompanying drawings.

### 1. Particle Coating Apparatus

First, the particle coating apparatus according to the embodiment will be described.

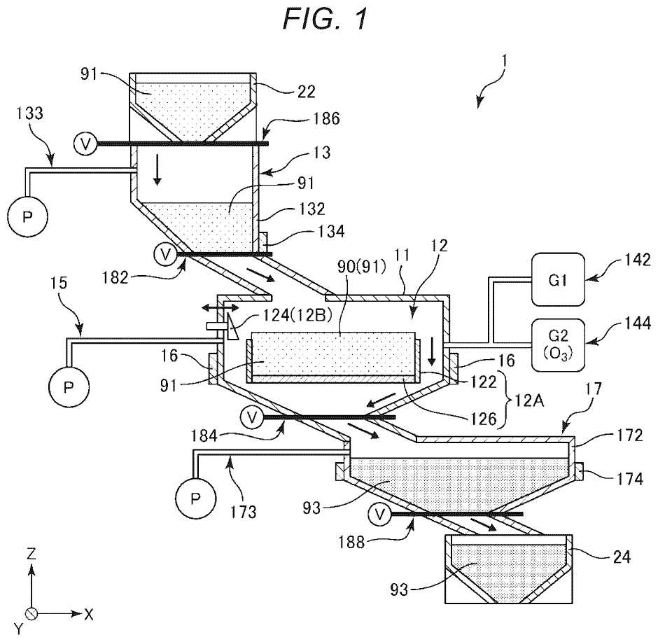

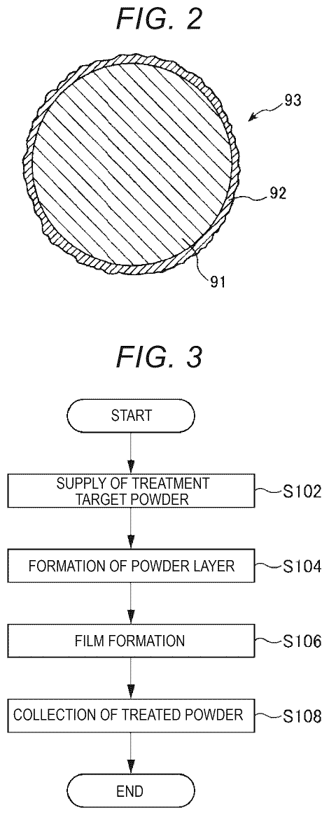

FIG. 1 is a cross-sectional view illustrating a particle coating apparatus 1 according to an embodiment. FIG. 2 is a cross-sectional view schematically showing an example of a coated particle 93 manufactured by the particle coating apparatus 1 shown in FIG. 1. In FIG. 1, for the sake of convenience of description, an X axis, a Y axis, and a Z axis are set as three axes orthogonal to each other, and each axis is indicated by an arrow. The Z axis is a vertical axis, and the X-Y plane is a horizontal plane. The base end side of the arrow is referred to as the minus side of each axis, and the tip end side is referred to as the plus side of each axis.

The particle coating apparatus 1 shown in FIG. 1 is an apparatus that forms a coating film 92 shown in FIG. 2 on a surface of a particle 91 by the atomic layer deposition (ALD) method. In the following description, the aggregate of the particles 91 is referred to as “treatment target powder”. The particle coating apparatus 1 includes a processing chamber 11, a powder layer holding unit 12, a powder supply unit 13, a material gas supply unit 142, an oxidizing agent supply unit 144, a processing chamber exhaust unit 15, a processing chamber heating unit 16, a powder collection unit 17, a supply switching unit 182, and a collection switching unit 184. In the particle coating apparatus 1, after the particles 91 of the treatment target powder are housed in the processing chamber 11, and the inside of the processing chamber 11 is exhausted by the processing chamber exhaust unit 15, the material gas supply unit 142 and the oxidizing agent supply unit 144 introduce the material gas G1 and the oxidizing agent G2. Further, the particles 91 of the treatment target powder are heated by the processing chamber heating unit 16. The material gas G1 introduced into the processing chamber 11 is decomposed, and decomposition products are adsorbed on the surfaces of the particles 91 of the treatment target powder, whereby the coating film 92 shown in FIG. 2 is finally formed. Thus, the coated particles 93 shown in FIG. 2 are obtained. In the following description, aggregate of the coated particles 93 is also referred to as “treated powder”.

The particle coating apparatus 1 shown in FIG. 1 is supplied with the treatment target powder from a supply hopper 22. The supply hopper 22 is a portable container that contains treatment target powder. The treated powder obtained by the particle coating apparatus 1 shown in FIG. 1 is discharged to a collection hopper 24 and is then collected. The collection hopper 24 is a portable container that contains the treated powder.

The processing chamber 11 is a container having rigidity and airtightness, and forms the coating film 92 on the surface of the particles 91 of the treatment target powder in a state where the treatment target powder is housed therein. The processing chamber 11 is maintained in a reduced pressure state by exhausting the inside thereof. Examples of the constituent material of the processing chamber 11 include a glass material such as quartz glass, a ceramic material such as alumina, and a metal material such as stainless steel, aluminum, or titanium.

The powder layer holding unit 12 is disposed in the processing chamber 11 and holds the treatment target powder supplied from the powder supply unit 13 in a layered state, specifically, in the state of a powder layer 90 shown in FIG. 1. The holding means maintaining the relative positions of the particles 91 so as not to change, and specifically means that the powder layer 90 is left at rest. The powder layer holding unit 12 illustrated in FIG. 1 includes a powder layer forming unit 12A and a powder layer discharging unit 12B. The powder layer forming unit 12A includes a frame body 122 and a stage 126. Meanwhile, the powder layer discharging unit 12B includes a squeegee 124.

The frame body 122 is a wall body that is provided in the processing chamber 11, rises from a bottom surface, and has a closed annular shape when viewed from vertically above. A space for accommodating the treatment target powder is formed inside the frame body 122.

The squeegee 124 moves in the X-axis direction along the upper end of the frame body 122. By the move of the squeegee 124, an upper surface of the treatment target powder housed inside the frame body 122 is formed. The treated powder protruding upward from the upper end of the frame body 122 is dragged laterally and discharged to the outside of the frame body 122. The treated powder thus discharged falls in the processing chamber 11 and is collected by the powder collection unit 17 disposed below the processing chamber 11.

The stage 126 is disposed inside the frame body 122 and moves up and down. Accordingly, the treatment target powder housed inside the frame body 122 can be pushed up from below, and a new powder layer 90 can be formed.

According to the powder layer holding unit 12 configured as described above, it is possible to easily repeat the processing until the treated powder is discharged after the treated powder is held as a layer. Therefore, the treated powder can be continuously and efficiently manufactured. The configuration of the powder layer holding unit 12 is not limited to the above. For example, the powder layer forming unit 12A may include a roller or the like, and may be configured to form the powder layer 90 by leveling the treatment target powder. Further, the powder layer discharging unit 12B may be configured to discharge the treated powder by a roller, a blower, or the like.

The material gas supply unit 142 and the oxidizing agent supply unit 144 are coupled to the processing chamber 11. The material gas supply unit 142 supplies the material gas G1 necessary for forming the coating film 92 into the processing chamber 11 and adjusts the partial pressure of the material gas G1 in the processing chamber 11. The material gas supply unit 142 includes, for example, a material gas reservoir, a pipe, a flow control valve, and so on. The oxidizing agent supply unit 144 supplies the oxidizing agent G2 necessary for forming the coating film 92 into the processing chamber 11 and adjusts the partial pressure of the oxidizing agent G2 in the processing chamber 11. The oxidizing agent supply unit 144 includes, for example, an oxidizing agent reservoir, a pipe, and a flow control valve. In FIG. 1, ozone O₃ is exemplified as the oxidizing agent G2. By using ozone as the oxidizing agent G2, it is possible to more efficiently form the coating film 92 which is denser and is uniform in film thickness. The material gas G1 and the oxidizing agent G2 are supplied together with a carrier gas containing an inert gas such as nitrogen gas or argon gas as a main component as necessary.

The processing chamber exhaust unit 15 exhausts the inside of the processing chamber 11. Accordingly, the inside of the processing chamber 11 can be depressurized. The processing chamber exhaust unit 15 includes, for example, a vacuum pump, a pressure gauge, a pipe, and an exhaust valve.

The processing chamber heating unit 16 heats the processing chamber 11 and accordingly heats the powder layer 90. Examples of the processing chamber heating unit 16 include a heater block, a film heater, a sheet heater, a sheathed heater, and an infrared radiation heater. In FIG. 1, the processing chamber heating unit 16 is disposed outside the processing chamber 11, but the arrangement of the processing chamber heating unit 16 is not limited thereto. For example, the processing chamber heating unit 16 may be disposed inside the processing chamber 11 or may be incorporated in a wall body constituting the processing chamber 11. The processing chamber heating unit 16 may be provided as necessary, and may be omitted.

By providing such a processing chamber heating unit 16, the temperature of the powder layer 90 and the temperatures of the material gas G1 and the oxidizing agent G2 can be optimized. Accordingly, it is possible to more efficiently form the coating film 92 which is denser and is uniform in film thickness.

The powder supply unit 13 includes an anterior chamber 132 disposed above the processing chamber 11. The anterior chamber 132 is a container having rigidity and airtightness, and accommodates the treatment target powder therein. The anterior chamber 132 maintains a reduced pressure state by exhaust of the inside. Examples of the constituent material of the anterior chamber 132 includes a glass material such as quartz glass, a ceramic material such as alumina, and a metal material such as stainless steel, aluminum, and titanium.

The powder supply unit 13 includes an anterior chamber exhaust unit 133 for exhausting the anterior chamber 132. The anterior chamber exhaust unit 133 includes, for example, a vacuum pump, a pressure gauge, a pipe, and an exhaust valve.

The powder supply unit 13 further includes an anterior chamber heating unit 134 that heats the anterior chamber 132. Examples of the anterior chamber heating unit 134 include the various heaters described above. In FIG. 1, the anterior chamber heating unit 134 is disposed outside the anterior chamber 132, but the arrangement of the anterior chamber heating unit 134 is not limited thereto. For example, the anterior chamber heating unit 134 may be disposed inside the anterior chamber 132 or may be incorporated in a wall body constituting the anterior chamber 132. The anterior chamber heating unit 134 may be provided as necessary, and may be omitted.

The supply switching unit 182 is disposed between the anterior chamber 132 and the processing chamber 11. The supply switching unit 182 has a function of switching the supply when the treatment target powder housed in the anterior chamber 132 is supplied into the processing chamber 11. Specifically, the supply switching unit 182 includes a flow path through which the treatment target powder passes in a state where the anterior chamber 132 and the processing chamber 11 are airtightly coupled, and a gate valve that opens and closes the flow path. As described above, the anterior chamber 132, the processing chamber 11, and the supply switching unit 182 include a so-called load lock mechanism. Through the supply switching unit 182, the powder supply unit 13 can supply the treatment target powder into the processing chamber 11 in a state of being isolated from the outside air. The gate valve is manually or electrically operated. When the gate valve is opened, the treatment target powder is supplied through the flow path. When the gate valve is closed, the supply of the treatment target powder is stopped.

The powder collection unit 17 includes a collection chamber 172 disposed below the processing chamber 11 outside the processing chamber 11. The collection chamber 172 is a container having rigidity and airtightness, and accommodates the treated powder therein. The collection chamber 172 maintains a reduced pressure state by exhaust of the inside. Examples of the constituent material of the collection chamber 172 include a glass material such as quartz glass, a ceramic material such as alumina, and a metal material such s stainless steel, aluminum, and titanium.

The powder collection unit 17 includes a collection chamber exhaust unit 173 for exhausting the collection chamber 172. The collection chamber exhaust unit 173 includes, for example, a vacuum pump, a pressure gauge, a pipe, and an exhaust valve.

The powder collection unit 17 further includes a collection chamber cooling unit 174 that cools the collection chamber 172. Examples of the collection chamber cooling unit 174 include a water-cooled cooler, an air-cooled cooler, and a Peltier element. In FIG. 1, the collection chamber cooling unit 174 is disposed outside the collection chamber 172, but the arrangement of the collection chamber cooling unit 174 is not limited thereto. For example, the collection chamber cooling unit 174 may be disposed inside the collection chamber 172 or may be incorporated in a wall body constituting the collection chamber 172. The collection chamber cooling unit 174 may be provided as necessary, and may be omitted.

The collection switching unit 184 is disposed between the processing chamber 11 and the collection chamber 172. The collection switching unit 184 has a function of switching the collection of the treated powder obtained in the processing chamber 11 when the treated powder is collected into the collection chamber 172. Specifically, the collection switching unit 184 includes a flow path through which the treated powder passes in a state where the processing chamber 11 and the collection chamber 172 are airtightly coupled, and a gate valve that opens and closes the flow path. As described above, the processing chamber 11, the collection chamber 172, and the collection switching unit 184 include a so-called load lock mechanism. Through the collection switching unit 184, the powder collection unit 17 can collect the treated powder into the collection chamber 172 in a state of being isolated from the outside air. The gate valve is manually or electrically operated. When the gate valve is opened, the treated powder passes through the flow path and is collected. When the gate valve is closed, the collection of the treated powder is stopped.

The particle coating apparatus 1 shown in FIG. 1 includes a supply hopper opening/closing unit 186 and a collection hopper opening/closing unit 188.

The supply hopper opening/closing unit 186 is disposed between the supply hopper 22 and the powder supply unit 13. The supply hopper opening/closing unit 186 has a function of opening and closing a flow path for supplying the treatment target powder housed in the supply hopper 22 into the anterior chamber 132. Specifically, the supply hopper opening/closing unit 186 includes a flow path through which the treatment target powder passes, and a gate valve that opens and closes the flow path. The gate valve is manually or electrically operated.

The collection hopper opening/closing unit 188 is disposed between the powder collection unit 17 and the collection hopper 24. The collection hopper opening/closing unit 188 has a function of opening and closing a flow path for discharging the treated powder housed in the collection chamber 172 to the collection hopper 24. Specifically, the collection hopper opening/closing unit 188 includes a flow path through which the treated powder passes and a gate valve that opens and closes the flow path. The gate valve is manually or electrically operated.

### 2. Treatment Target Powder

Next, the treatment target powder will be described.

The coated particle 93 shown in FIG. 2 includes the particle 91 of the treatment target powder and the coating film 92.

The constituent material of the particles 91 (constituent material of the treatment target powder) is not particularly limited, and examples thereof include a metal material, a ceramic material, a glass material, a silicon material, a carbon material, and a resin material. The constituent material of the particles 91 may be a soft magnetic metal material. When the particles 91 made of the soft magnetic metal material are used in a magnetic component such as an inductor, it is necessary to ensure insulation between the particles 91. By using the particle coating apparatus 1 described above, it is possible to form the coating film 92 having a sufficiently thin film thickness and a high coverage. As a result, the coated particles 93 capable of enhancing the magnetic characteristics and the insulation characteristics of the magnetic component are obtained. In addition, since the coating film 92 formed by the atomic layer deposition method is dense, for example, the coating film 92 contributes to the realization of the coated particle 93 having high insulating properties.

Examples of the soft magnetic metal material include, for example, pure iron, various Fe-based alloys such as an Fe—Si-based alloy such as silicon steel, an Fe—Ni-based alloy such as permalloy, an Fe—Co-based alloy such as permendur, an Fe—Si—Al-based alloy such as sendust, and an Fe—Cr—Si-based alloy, various Ni-based alloys, various Co-based alloys, and various amorphous alloys. Among these, examples of the amorphous alloys include Fe-based alloys such as Fe—Si—B-based, Fe—Si—B—C-based, Fe—Si—B—Cr—C-based, Fe—Si—Cr-based, Fe—B-based, Fe—P—C-based, Fe—Co—Si—B-based, Fe—Si—B—Nb-based, and Fe—Zr—B-based alloys, Ni-based alloys such as Ni—Si—B-based and Ni—P—B-based alloys, and Co-based alloys such as Co—Si—B-based alloys.

An average particle diameter D50 of the particles 91 is not particularly limited, but is preferably 0.1 μm or more and 50.0 μm or less, more preferably 0.5 μm or more and 10.0 μm or less, and still more preferably 1.0 μm or more and 3.5 μm or less. The average particle diameter D50 of the particles 91 can be obtained as a particle diameter when the cumulative amount from the smaller diameter side reaches 50% in a cumulative particle size distribution on a volume basis obtained by laser diffractometry.

### 3. Method of Coating Particles

Next, the method of coating the particles according to the embodiment will be described.

FIG. 3 is a process diagram illustrating the method of coating the particles according to the embodiment.

The method of coating the particles shown in FIG. 3 includes a treatment target powder supply step S102, a powder layer forming step S104, a film forming step S106, and a collection step S108. In the following description, a method using the above-described particle coating apparatus 1 will be described as an example, but the method of coating the particles according to the present disclosure may be a method using an apparatus other than the particle coating apparatus 1.

### 3.1. Treatment Target Powder Supply Step

In the treatment target powder supply step S102, the supply hopper opening/closing unit 186 is opened to transfer the treatment target powder from the supply hopper 22 into the anterior chamber 132. When a predetermined amount of the treatment target powder is transferred, the supply hopper opening/closing unit 186 is closed.

Thereafter, the inside of the anterior chamber 132 may be exhausted and depressurized as necessary. The pressure in the anterior chamber 132 is not particularly limited, but is preferably 10 kPa or less, and more preferably 1 kPa or less. Accordingly, it is possible to prevent oxygen and moisture from remaining in the anterior chamber 132, and it is possible to more reliably prevent oxidation, deterioration, and the like of the treatment target powder housed in the anterior chamber 132. The lower limit value of the pressure in the anterior chamber 132 may not be particularly set, but is preferably 1×10⁻⁵ Pa or more, and more preferably 1×10⁻³ Pa or more in consideration of an increase in cost for maintaining a reduced pressure state, a possibility that the effect due to the depressurization cannot sufficiently be obtained, and so on.

The treatment target powder housed in the anterior chamber 132 may be heated as necessary. A heating temperature of the treatment target powder is not particularly limited, and is preferably 30° C. or higher and 500° C. or lower, and more preferably 50° C. or higher and 300° C. or lower. Accordingly, sufficient preheating can be applied to the treatment target powder. As a result, the coating film 92 can be formed with a more uniform film thickness in the film forming step S106 described later.

Subsequently, the supply switching unit 182 is opened, and the treatment target powder housed in the anterior chamber 132 is supplied into the processing chamber 11. Since the treatment target powder is supplied through the supply switching unit 182, it can be supplied in an environment isolated from the outside air. Accordingly, oxidation, deterioration, and the like of the treatment target powder due to contact with the outside air can be prevented.

In the present embodiment, the treatment target powder is supplied to the inside of the frame body 122. Accordingly, the treatment target powder can be held in a predetermined area in the processing chamber 11. As a result, in the film forming step S106 to be described later, the treatment target powder can be kept in an area suitable for film formation, and therefore the coating film 92 can be formed with a more uniform film thickness.

When the supply switching unit 182 is opened, it is preferable that the inside of the anterior chamber 132 is exhausted in advance. Accordingly, when the inside of the processing chamber 11 is depressurized, the treatment target powder can be supplied without restoring the inside of the processing chamber 11 to the atmospheric pressure. As a result, the time and cost required for the depressurization can be saved, and the manufacture of the coated particles 93 can be speeded up and the cost can be reduced. On this occasion, it is preferable to make the pressure difference between the anterior chamber 132 and the processing chamber 11 close to zero. As a result, it is possible to prevent the treatment target powder from flying up due to the pressure difference.

After the treatment target powder is supplied, the supply switching unit 182 is closed.

### 3.2. Powder Layer Forming Step

In the powder layer forming step S104, the powder layer 90 that is formed by laying the treatment target powder supplied into the processing chamber 11 in a layer shape is formed. The powder layer 90 is formed, for example, as follows.

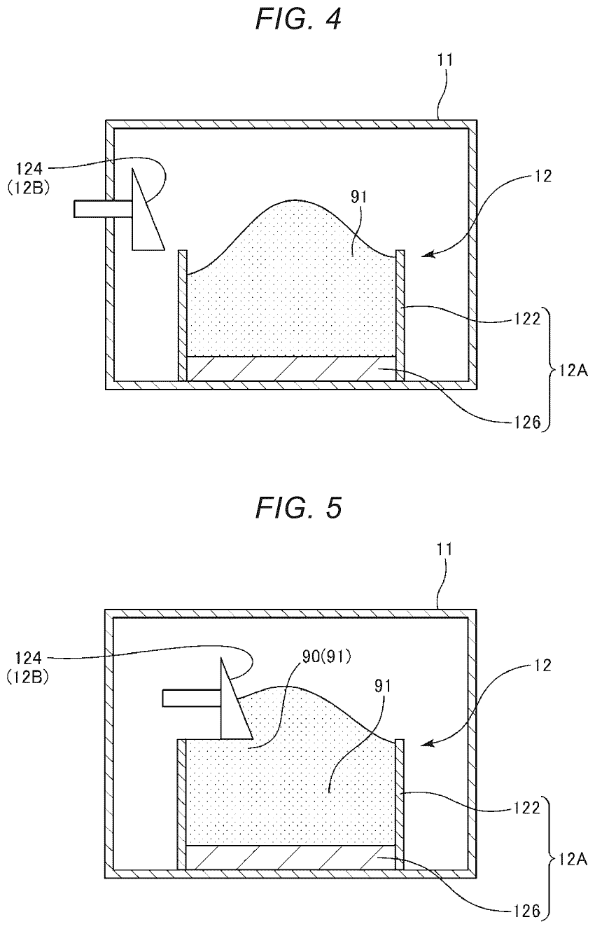

FIGS. 4 to 8 are cross-sectional views illustrating an example of a method of forming the powder layer 90.

First, as shown in FIG. 4, the treatment target powder (particles 91) is supplied into the frame body 122. The supply amount of the treatment target powder is preferably equal to or larger than the inner volume of the frame body 122.

Subsequently, as shown in FIG. 5, the squeegee 124 is moved to level the upper surface of the treatment target powder. Thus, the upper surface of the treatment target powder can be planarized. As a result, the vicinity of an upper surface of the treatment target powder forms the powder layer 90 to be subjected to film forming processing described later. The powder layer 90 is held by being supported by the frame body 122.

The method of forming the powder layer 90 is not limited to the above-described method. For example, the powder layer 90 may be formed by leveling the treatment target powder by applying vibration or the like.

Further, the powder layer 90 may be subjected to a pretreatment prior to the formation of the coating film 92 described later. Examples of the pretreatment include an ozone treatment, a radical treatment, an ultraviolet radiation treatment, a plasma treatment, a corona treatment, a drying treatment, and a solvent treatment. The pretreatment may be performed in the anterior chamber 132.

### 3.3. Film Forming Step

In the film forming step S106, the coating film 92 is formed at the powder layer 90 in the processing chamber 11 by the atomic layer deposition method. The coating film 92 is formed, for example, as follows.

First, the treatment target powder housed in the processing chamber 11 is heated. This heating may be performed temporally overlapping the film formation of the coating film 92 described later, or may be performed separately from the film formation, that is, without temporally overlapping the film formation. The heating of the treatment target powder may be performed as necessary, and may be omitted.

A heating temperature is not particularly limited, and is preferably 30° C. or more and 500° C. or less, and more preferably 80° C. or more and 300° C. or less. In particular, when the constituent material of the particles 91 is a material having low heat resistance such as a resin material, the heating temperature is preferably 30° C. or more and 150° C. or less, and more preferably 30° C. or more and 100° C. or less. The heating time at such a heating temperature is appropriately set according to the film thickness of the coating film 92, and is preferably 0.1 hour or more and 300 hours or less, more preferably 1 hour or more and 200 hours or less, and still more preferably 5 hours or more and 100 hours or less.

The pressure in the processing chamber 11 before the introduction of the material gas G1 and the oxidizing agent G2 is not particularly limited, but is preferably 10 kPa or less, and more preferably 1 kPa or less. Accordingly, it is possible to prevent oxygen and moisture from remaining in the processing chamber 11. The lower limit value of the pressure in the processing chamber 11 may not be particularly set, but is preferably 1×10⁻⁵ Pa or more, and more preferably 1×10⁻³ Pa or more in consideration of an increase in cost for maintaining the reduced pressure state, a possibility that the effect due to the depressurization cannot sufficiently be obtained, and so on.

Subsequently, the material gas G1 is introduced into the processing chamber 11 by the material gas supply unit 142. The material gas G1 thus introduced is adsorbed on the surfaces of the particles 91 of the treatment target powder. On this occasion, when the material gas G1 is adsorbed to the surfaces of the particles 91, the material gas G1 is less likely to be further adsorbed to other layers. Therefore, the film thickness of the coating film 92 finally obtained can be controlled with high accuracy. In addition, the material gas G1 also flows around and adsorbs to a portion that becomes a shadow or a gap. Accordingly, the thickness of the powder layer 90 shown in FIG. 1 corresponds to the depth into which the material gas G1 can enter from the upper surface of the treatment target powder thus leveled.

Examples of the material gas G1 include a gas containing a precursor of the coating film 92. Specifically, for example, when the silicon oxide-based coating film 92 is formed, examples of the material gas G1 include dimethylamino silane, methylethylaminosilane, diethylamino silane, tris dimethylamino silane, bis diethylamino silane, and bis tertiary-butylaminosilane.

Examples of the constituent material of the coating film 92 to be formed include oxides such as hafnium oxide, tantalum oxide, titanium oxide, and chromium oxide, and nitrides such as aluminum nitride, titanium nitride, and tantalum nitride in addition to silicon oxide.

Subsequently, after the material gas G1 in the processing chamber 11 is discharged with the processing chamber exhaust unit 15, an inert gas such as nitrogen or argon is introduced as necessary. Thus, the material gas G1 is replaced. Introduction of the inert gas can be performed by the same method as that of introduction of the material gas G1 and the oxidizing agent G2, although not shown.

Subsequently, after the inert gas in the processing chamber 11 is discharged with the processing chamber exhaust unit 15, the oxidizing agent G2 is introduced into the processing chamber 11 with the oxidizing agent supply unit 144. Examples of the oxidizing agent G2 include plasma oxygen and water vapor in addition to ozone shown in FIG. 1.

The oxidizing agent G2 reacts with the material gas G1 adsorbed on the surfaces of the particles 91 of the treatment target powder, and forms the coating film 92. Similarly to the material gas G1, the oxidizing agent G2 also goes around to a portion to be shaded or a gap. Accordingly, the thickness of the powder layer 90 shown in FIG. 1 corresponds to the depth into which the oxidizing agent G2 can enter from the upper surface of the treatment target powder thus leveled.

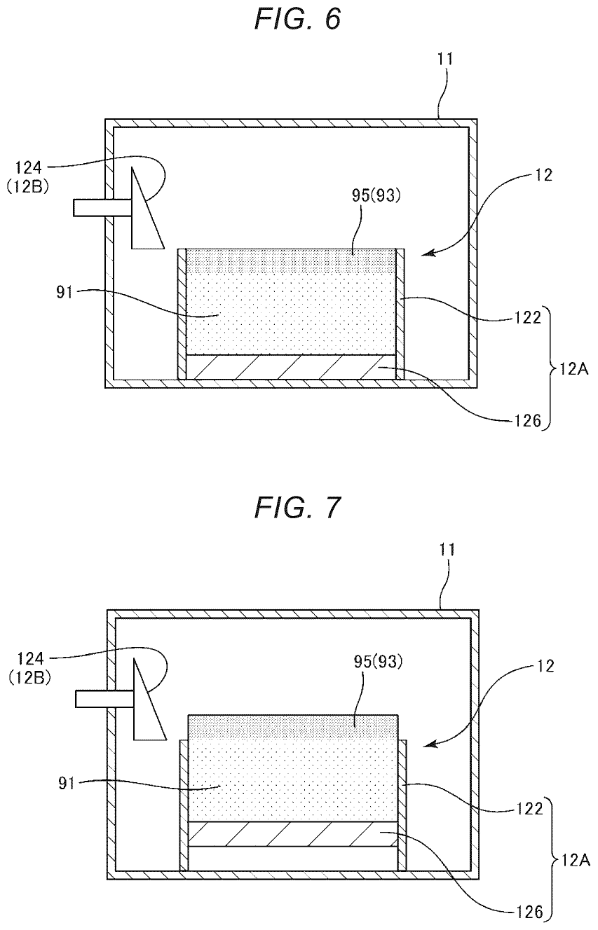

Subsequently, after the oxidizing agent G2 in the processing chamber 11 is discharged with the processing chamber exhaust unit 15, an inert gas is introduced as necessary to replace the oxidizing agent G2. As described above, the coating film 92 is formed, and the coated particles 93 are obtained. The powder layer formed of the coated particles 93 is referred to as a powder layer 95 shown in FIG. 6.

Note that, the introduction and the discharge of the material gas G1, and the introduction and the discharge of the oxidizing agent G2 may be repeated according to the target film thickness of the coating film 92. The film thickness can be increased according to the number of repetitions. Accordingly, a desired film thickness can easily be obtained.

Thereafter, the coated particles 93 may be subjected to a posttreatment as necessary. Examples of the posttreatment include a destaticizing treatment and a radical treatment.

Among them, the destaticizing treatment is a treatment for reducing the amount of electric charge due to charging of the coated particles 93. For example, an ionizer is used for the destaticizing treatment.

The film thickness of the coating film 92 is not particularly limited, but is, for example, preferably 1 nm or more and 500 nm or less, more preferably 2 nm or more and 300 nm or less, and still more preferably 4 nm or more and 200 nm or less. With such a film thickness, the film can be uniformly formed in a relatively short time. In addition, according to the atomic layer deposition method, the dense coating film 92 can be formed, and thus a sufficient insulation capability can be obtained even with such a thin film thickness. In this case, the coating film 92 having good insulation properties is obtained. The film thickness of the coating film 92 is an average value of measurement values obtained at five or more positions by observing a cross section of the coated particle 93 in an enlarged manner.

The formation of the coating film 92 as described above is performed in a state where the powder layer 90 is left stationary. Therefore, the coating film 92 having a uniform film thickness can be formed.

### 3.4. Collection Step

In the collection step S108, first, as shown in FIG. 7, the stage 126 is raised. Accordingly, the powder layer 95 in which the coating film 92 is formed can be pushed up above the frame body 122.

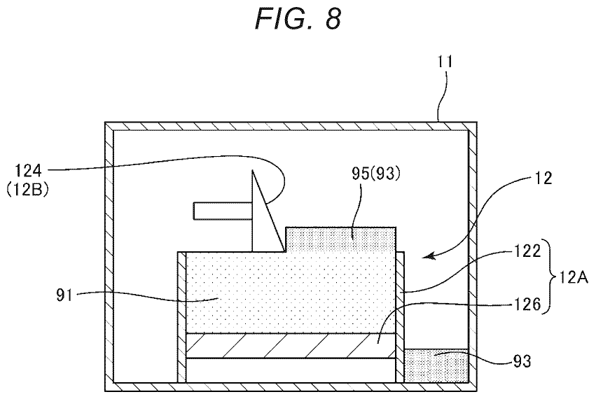

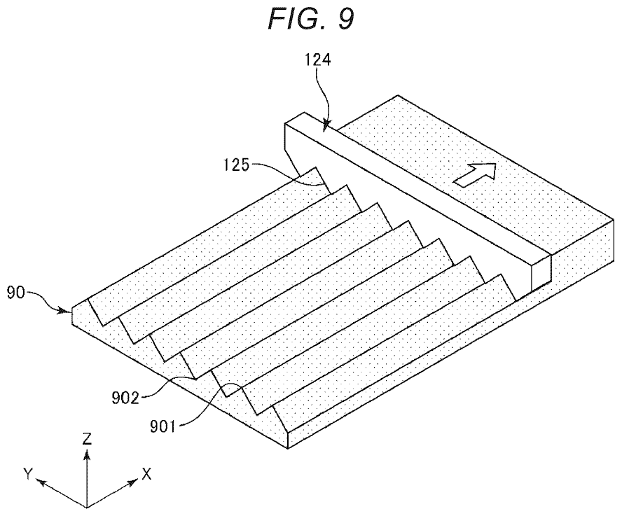

Subsequently, as shown in FIG. 8, the powder layer 95 is drawn in a lateral direction by the squeegee 124. Accordingly, the powder layer 95 can be discharged to the outside of the frame body 122. The treated powder (coated particles 93) thus discharged falls in the processing chamber 11 and is stored on the collection switching unit 184. The lateral direction refers to any direction along a horizontal plane. In addition, the discharge means that the powder layer 95 is moved to thereby empty a film formation region (space in which the powder layer 95 is present).

Subsequently, the collection switching unit 184 is opened to collect the treated powder into the collection chamber 172. Since the treated powder is collected via the collection switching unit 184, the treated powder can be collected in an environment isolated from the outside air. This can prevent oxidation, deterioration, and the like of the treated powder due to contact with the outside air.

When the collection switching unit 184 is opened, the inside of the collection chamber 172 is preferably exhausted in advance. Accordingly, the treated powder can be collected without restoring the inside of the processing chamber 11 to the atmospheric pressure. As a result, the time and cost required for the depressurization can be saved, and the manufacture of the coated particles 93 can be speeded up and the cost can be reduced. On this occasion, it is preferable to make the pressure difference between the processing chamber 11 and the collection chamber 172 close to zero. Accordingly, it is possible to prevent the treated powder from flying up due to the pressure difference.

After collecting the treated powder, the collection switching unit 184 is closed.

The pressure in the collection chamber 172 is not particularly limited, but is preferably 10 kPa or less, and more preferably 1 kPa or less. Accordingly, it is possible to prevent oxygen and moisture from remaining in the collection chamber 172, and it is possible to more reliably prevent oxidation, deterioration, and the like of the treated powder collected in the collection chamber 172. The lower limit value of the pressure in the collection chamber 172 may not be particularly set, but is preferably 1×10⁻⁵ Pa or more, and more preferably 1×10⁻³ Pa or more in consideration of an increase in cost for maintaining a reduced pressure state, a possibility that the effect due to the depressurization cannot sufficiently be obtained, and so on.

The heat of the treated powder collected in the collection chamber 172 may be radiated by the collection chamber cooling unit 174 as needed. As a result, the temperature of the treated powder can be lowered, and the modification caused by exposure of the high-temperature treated powder to the atmosphere can be prevented. In addition, the time until the treated powder is exposed to the atmosphere can be shortened.

After the heat radiation of the treated powder, the collection chamber 172 is restored to the atmospheric pressure. Then, the collection hopper opening/closing unit 188 is opened to transfer the treated powder from the collection chamber 172 to the collection hopper 24. After the treated powder is transferred, the collection hopper opening/closing unit 188 is closed.

In such a manner as described above, the treated powder (the coated particles 93) can be collected.

### 4. Modified Examples

Next, the particle coating apparatus 1 according to a first modified example of the embodiment will be described.

FIG. 9 is a perspective view illustrating the squeegee 124 provided to the particle coating apparatus 1 according to the first modified example.

Hereinafter, the first modified example will be described, but in the following description, differences from the embodiment described above will be mainly described, and description of similar matters will be omitted.

The first modified example is substantially the same as the above-described embodiment except that the squeegee 124 has a different shape.

The squeegee 124 shown in FIG. 9 has a plate shape extending along the Y axis and moves along the X axis. Thus, an upper surface of the treatment target powder along the X-Y plane is formed while leveling the treatment target powder. As a result, the powder layer 90 having this upper surface is obtained.

The squeegee 124 shown in FIG. 9 has a ridge line 125. The shape of the ridge line 125 is reflected on the upper surface of the powder layer 90. The ridge line 125 illustrated in FIG. 9 has a corrugated shape. Therefore, when the squeegee 124 having the ridge line 125 shown in FIG. 9 is dragged to discharge the powder layer 95, it is possible to newly form the powder layer 90 having a corrugated upper surface. That is, the shape of the powder layer 90 left on the upper surface (obverse surface) by the squeegee 124 is a shape including convex lines 901 or grooves 902 extending along the X axis.

By using the squeegee 124 having the ridge line 125 corrugated in such a manner, it is possible to further increase the surface area of the upper surface of the powder layer 90 compared to when using, for example, a squeegee having a linear ridge line. Accordingly, when the coating film 92 is formed in the powder layer 90, the material gas G1 and the oxidizing agent G2 can be made to penetrate deeper. As a result, it is possible to increase the amount of the treated powder that can be manufactured at a time, and increase the manufacturing speed of the treated powder.

The shape of the ridge line 125 is not limited to the corrugated shape shown in FIG. 9, and the ridge line 125 may sufficiently be configured such that the shape of the ridge line 125 left on the upper surface of the powder layer 90 by the squeegee 124 includes the convex lines 901 or the grooves 902. That is, it is sufficient for the ridge line not to be a straight line, but has a shape including some convex portion or concave portion. However, in view of the easiness in homogenizing the penetration amount of the material gas G1 or the oxidizing agent G2, it is preferable that the shape is configured in a repetitive pattern as shown in FIG. 9. The powder layer 90 may sufficiently include the convex lines 901 or the grooves 902, but preferably includes both of them from the viewpoint of increasing the surface area.

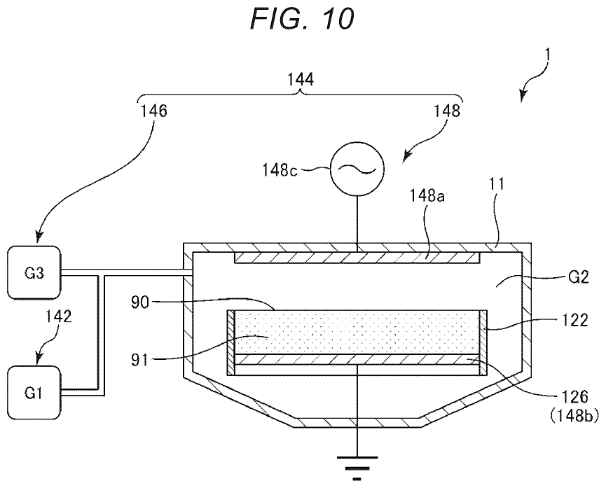

FIG. 10 is a cross-sectional view illustrating the processing chamber 11 provided to the particle coating apparatus 1 according to a second modified example. Note that in FIG. 10, illustration of part of the configuration is omitted.

Hereinafter, the second modified example will be described, but in the following description, differences from the above-described embodiment will mainly be described, and description of similar matters will be omitted.

The second modified example is the same as the embodiment except that the oxidizing agent supply unit 144 includes an oxygen gas supply unit 146 and a plasma generating unit 148 shown in FIG. 10.

The oxygen gas supply unit 146 supplies the oxygen gas G3 necessary for generating plasma oxygen into the processing chamber 11, and adjusts the partial pressure of the oxygen gas G3 in the processing chamber 11. The oxygen gas supply unit 146 includes, for example, an oxygen gas reservoir, a pipe, and a flow control valve.

The plasma generating unit 148 includes an upper electrode 148a, a lower electrode 148b, and a high frequency power supply 148c. The upper electrode 148a is disposed at the upper portion of the processing chamber 11 and is coupled to the high frequency power supply 148c. The lower electrode 148b is disposed inside the frame body 122 and is grounded.

The oxygen gas G3 is supplied into the processing chamber 11 by the oxygen gas supply unit 146, and in this state, the oxygen gas G3 is changed into plasma oxygen by the plasma generating unit 148. That is, plasma oxygen is generated in the processing chamber 11. Accordingly, plasma oxygen generated in the processing chamber 11 can be used as the oxidizing agent G2. By using plasma oxygen as the oxidizing agent G2, the temperature when forming the coating film 92 can be lowered. That is, a film can be formed at a lower temperature. Accordingly, even when the constituent material of the particles 91 has low heat resistance, the coating film 92 can be formed.

The high frequency power supply 148c may be coupled to the lower electrode 148b and the upper electrode 148a may be grounded.

Further, the upper electrode 148a and the lower electrode 148b may be coupled to the high frequency power supply 148c so as to have respective polarities opposite to each other. In this case, the generated plasma oxygen can be drawn toward the lower electrode 148b side. As a result, the plasma oxygen as the oxidizing agent G2 can penetrate deeper into the powder layer 90. As a result, it is possible to increase the amount of the treated powder that can be manufactured at a time, and increase the manufacturing efficiency of the treated powder.

In such a modified example as described above, substantially the same advantages as those of the embodiment described above can be obtained.

### 5. Advantages Exerted by Embodiment or Modified Examples

As described above, the particle coating apparatus 1 according to the embodiment or the modified examples is an apparatus for forming the coating film 92 on the surface of the particle 91 of the treatment target powder by the atomic layer deposition method, and includes the processing chamber 11, the powder supply unit 13, the supply switching unit 182, the material gas supply unit 142, the oxidizing agent supply unit 144, the processing chamber exhaust unit 15, and the powder layer holding unit 12. The powder supply unit 13 has the anterior chamber 132 for housing the treatment target powder, and supplies the treatment target powder into the processing chamber 11 in a state of being isolated from the outside air. The supply switching unit 182 is disposed between the anterior chamber 132 and the processing chamber 11 and switches the supply of the treatment target powder. The material gas supply unit 142 supplies the material gas G1 into the processing chamber 11. The oxidizing agent supply unit 144 supplies the oxidizing agent G2 into the processing chamber 11. The processing chamber exhaust unit 15 exhausts the inside of the processing chamber 11. The powder layer holding unit 12 is disposed in the processing chamber 11, and holds the powder layer 90 formed of the treatment target powder which is supplied from the anterior chamber 132, and is laid in a layer.

According to such a configuration, since the powder layer 90 is used for forming the coating film 92 in a state where the powder layer 90 is left at rest, the coating film 92 can be formed with a uniform film thickness. In addition, since the powder supply unit 13 can supply the treatment target powder into the processing chamber 11 while maintaining the airtightness of the anterior chamber 132 housing the treatment target powder, the treatment target powder can be supplied without restoring the pressure in the processing chamber 11 to the atmospheric pressure by, for example, reducing the pressure in the anterior chamber 132 in advance. Therefore, according to the above-described configuration, the particle coating apparatus 1 capable of efficiently manufacturing the particles 91 coated with the thin coating film 92 having a uniform film thickness, that is, the coated particles 93 can be obtained.

In the particle coating apparatus 1, the powder layer holding unit 12 may include the powder layer forming unit 12A and the powder layer discharging unit 12B. The powder layer forming unit 12A has the frame body 122 that accommodates the treatment target powder before the coating film 92 is formed therein, and forms the powder layer 90 before the coating film 92 is formed by supporting the treatment target powder with the frame body 122. The powder layer discharging unit 12B has the squeegee 124, and discharges the powder layer 95 having the coating film 92 formed thereon from the powder layer forming unit 12A by drawing the powder layer 95 having the coating film 92 formed therein in the lateral direction with the squeegee 124.

According to such a configuration, it is possible to continuously and efficiently manufacture the powder layer 95 after the coating film 92 is formed.

In the particle coating apparatus 1, the squeegee 124 has the ridge line 125 that comes into contact with the treatment target powder when the powder layer 95 is drawn. The ridge line 125 may be configured such that the shape of the ridge line 125 left on the surface of the treatment target powder dragged by the squeegee 124 is a shape including the convex lines or the grooves.

According to such a configuration, the powder layer 90 having the large surface area can be formed. Accordingly, when the coating film 92 is formed in the powder layer 90, the material gas G1 and the oxidizing agent G2 can be made to penetrate deeper. As a result, it is possible to increase the amount of the treated powder that can be manufactured at a time, and increase the manufacturing efficiency of the treated powder.

The oxidizing agent G2 may be ozone. In this case, the particle coating apparatus 1 may further include the processing chamber heating unit 16. The processing chamber heating unit 16 heats the powder layer 90.

According to such a configuration, it is possible to more efficiently form the coating film 92 which is denser and has a uniform film thickness.

The oxidizing agent G2 may be plasma oxygen. In this case, the oxidizing agent supply unit 144 may include the oxygen gas supply unit 146 and the plasma generating unit 148. The oxygen gas supply unit 146 supplies the oxygen gas G3 into the processing chamber 11. The plasma generating unit 148 converts the oxygen gas G3 into plasma oxygen.

According to such a configuration, plasma oxygen can be used as the oxidizing agent G2, and the temperature at the time of forming the coating film 92 can be lowered accordingly. That is, a film can be formed at a lower temperature. Accordingly, even when the constituent material of the particles 91 has low heat resistance, the coating film 92 can be formed.

The particle coating apparatus 1 may further include the powder collection unit 17 and the collection switching unit 184. The powder collection unit 17 is disposed outside the processing chamber 11 and collects the powder layer 95 after the coating film 92 is formed in a state of being isolated from the outside air. The collection switching unit 184 is disposed between the processing chamber 11 and the powder collection unit 17, and switches the collection of the powder layer 95.

According to such a configuration, for example, by reducing the pressure in the collection chamber 172 in advance, the treated powder can be collected without restoring the pressure in the processing chamber 11 to the atmospheric pressure.

In addition, the method of coating the particles according to the embodiment or the modified examples is a method of forming the coating film 92 on the surface of the particles 91 of the treatment target powder using the atomic layer deposition method, and includes the treatment target powder supply step S102, the powder layer forming step S104, and the film forming step S106. In the treatment target powder supply step S102, the treatment target powder housed in the anterior chamber 132 airtightly coupled to the processing chamber 11 is supplied into the processing chamber 11 in a state of being isolated from the outside air. In the powder layer forming step S104, the treatment target powder supplied into the processing chamber 11 is laid into a layer to form the powder layer 90. In the film forming step S106, the coating film 92 is formed at the powder layer 90 in the processing chamber 11 by the atomic layer deposition method.

According to such a configuration, since the powder layer 90 is used for forming the coating film 92 in a state where the powder layer 90 is left at rest, the coating film 92 can be formed with a uniform film thickness. In addition, since the powder supply unit 13 can supply the treatment target powder into the processing chamber 11 while maintaining the airtightness of the anterior chamber 132 housing the treatment target powder, the treatment target powder can be supplied without restoring the pressure in the processing chamber 11 to the atmospheric pressure by, for example, reducing the pressure in the anterior chamber 132 in advance. Thus, according to the above-described configuration, the particles 91 coated with the thin coating film 92 having a uniform film thickness, that is, the coated particles 93 can efficiently be manufactured.

In addition, the treatment target powder supply step S102 (step of supplying the treatment target powder into the processing chamber 11) may include an operation of supplying the treatment target powder into the frame body 122 disposed in the processing chamber 11.

According to such a configuration, since the treatment target powder can be kept in a range suitable for the film formation, the coating film 92 can be formed with a more uniform film thickness.

The method of coating the particles according to the embodiment or the modified examples includes a collection step S108. In the collection step S108, the powder layer 95 in which the coating film 92 is formed is collected. Further, the collection step S108 (step of collecting the powder layer 95) includes an operation of drawing the powder layer 95 in the lateral direction after the coating film 92 is formed.

According to such a configuration, the powder layer 95 can be discharged and collected from the film formation region.

The treatment target powder may be formed of a soft magnetic metal material. Further, the coating film 92 may be formed of an insulating material.

According to such a configuration, it is possible to form the coating film 92 having a sufficiently thin film thickness and a high density and coverage, and thus it is possible to obtain the coated particles 93 capable of realizing a magnetic component having excellent magnetic characteristics and insulating characteristics.

Although the particle coating apparatus and the method of coating the particles according to the present disclosure have been described above based on the illustrated embodiment, the present disclosure is not limited thereto.

For example, the particle coating apparatus according to the present disclosure may be what is obtained by replacing each unit of the embodiment described above with any component having the same function, or what is obtained by adding any constituent to the embodiment described above. In addition, the method of coating the particles according to the present disclosure may be what is obtained by adding a step having any purpose to the embodiment described above.

What is claimed is:

1. A particle coating apparatus configured to form a coating film on a surface of a particle of a treatment target powder using an atomic layer deposition method, comprising:
a processing chamber;
a powder supply unit which includes an anterior chamber configured to house the treatment target powder, and which is configured to supply the treatment target powder into the processing chamber in a state of being isolated from outside air;
a supply switching unit which is disposed between the anterior chamber and the processing chamber, and which is configured to switch supply of the treatment target powder;
a material gas supply unit configured to supply a material gas into the processing chamber;
an oxidizing agent supply unit configured to supply an oxidizing agent into the processing chamber;
a processing chamber exhaust unit configured to exhaust the processing chamber; and
a powder layer holding unit which is disposed in the processing chamber, and which is configured to hold a powder layer formed of the treatment target powder supplied from the anterior chamber and laid in a layer.

2. The particle coating apparatus according to claim 1, wherein
the powder layer holding unit includes
a powder layer forming unit which includes a frame body configured to house the treatment target powder to be coated with the coating film inside, and which is configured to support the treatment target powder with the frame body to thereby form the powder layer to be coated with the coating film, and
a powder layer discharging unit which includes a squeegee, and which is configured to draw the powder layer coated with the coating layer in a lateral direction with the squeegee to thereby discharge the powder layer coated with the coating film from the powder layer forming unit.

3. The particle coating apparatus according to claim 2, wherein
the squeegee has a ridge line which is configured to come into contact with the treatment target powder when drawing the powder layer, and
the ridge line is configured such that a shape of the ridge line which is left on a surface of the treatment target powder dragged by the squeegee is a shape including a convex line or a groove.

4. The particle coating apparatus according to claim 1, further comprising:
a processing chamber heating unit configured to heat the powder layer, wherein
the oxidizing agent is ozone.

5. The particle coating apparatus according to claim 1, wherein
the oxidizing agent is plasma oxygen, and
the oxidizing agent supply unit includes
an oxygen gas supply unit which is configured to supply oxygen gas into the processing chamber, and
a plasma generating unit which is configured to convert the oxygen gas into the plasma oxygen.

6. The particle coating apparatus according to claim 1, further comprising:
a powder collection unit which is disposed outside the processing chamber, and which is configured to collect the powder layer coated with the coating film in a state of being isolated from outside air; and
a collection switching unit which is disposed between the processing chamber and the powder collection unit, and which is configured to switch collection of the powder layer.

7. A method of coating a particle for forming a coating film on a surface of a particle of a treatment target powder using an atomic layer deposition method, the method comprising:
supplying the treatment target powder housed in an anterior chamber airtightly coupled to a processing chamber into the processing chamber in a state of being isolated from outside air;
forming a powder layer by laying the treatment target powder supplied into the processing chamber in a layer; and
forming the coating film in the powder layer in the processing chamber using the atomic layer deposition method.

8. The method of coating the particle according to claim 7, wherein
the supplying the treatment target powder into the processing chamber includes an operation of supplying the treatment target powder into a frame body disposed in the processing chamber.

9. The method of coating the particle according to claim 7, further comprising:
collecting the powder layer coated with the coating film, wherein
the collecting the powder layer includes an operation of drawing the powder layer coated with the coating film in a lateral direction.

10. The method of coating the particle according to claim 7, wherein
the treatment target powder is made of a soft magnetic metal material, and
the coating film is made of an insulating material.
